(19) United States
(12) Patent Application Publication
(10) Pub. No.: US 2013/0057114 A1
(43) Pub. Date: Mar. 7, 2013

(54) Piezoelectric Multilayer Component and Method for Producing a Piezoelectric Multilayer Component

(71) Applicants: Alexander Glazunov, Deutschlandsberg (AT); Oliver Dernovsek, Lieboch (AT)

(72) Inventors: Alexander Glazunov, Deutschlandsberg (AT); Oliver Dernovsek, Lieboch (AT)

(73) Assignee: EPCOS AG, Muenchen (DE)

(21) Appl. No.: 13/580,598

(22) PCT Filed: Feb. 21, 2011
(86) PCT No.: PCT/EP11/52527

§ 371 Date: Oct. 25, 2012

(30) Foreign Application Priority Data
Feb. 22, 2010 (DE) 10 2010 008 775.0

(51) Int. Cl. H01L 41/083; H04R 31/00

(52) U.S. Cl. 310/365; 29/25.35

(57) ABSTRACT

The invention relates to a piezoelectric multilayer component as an intermediate, which comprises a stack of piezoelectric layers arranged on top of one another. The stack comprises an active region having electrode layers arranged between the piezoelectric layers and at least one inactive region, wherein the active region on the end product of the piezoelectric multilayer component is provided for the purpose of deforming when a voltage is applied to the electrode layers. The inactive region contains at least one sacrificial layer which comprises an electrically insulating material and a metal, wherein the metal can diffuse at least partially from the sacrificial layer into the piezoelectric layers of the inactive region by heating the multilayer component.

This patent application is a national phase filing under section 371 of PCT/EP2011/052527, filed Feb. 21, 2011, which claims the priority of German patent application 10 2010 008 775.0, filed Feb. 22, 2010, each of which is incorporated herein by reference in its entirety.

### TECHNICAL FIELD

The invention relates to a piezoelectric component comprising piezoelectric layers.

### BACKGROUND

Multilayer piezoelectric components, such as multilayer piezoelectric actuators, for instance, comprise a plurality of layers of a piezoelectric material. Piezoelectric actuators can be used, for example, for actuating an injection valve in a motor vehicle.

Piezoelectric actuators are known, for example, from DE 10 2004 031 404 A1, DE 10 2005 052 686 A1 and EP 1926156 A2.

### SUMMARY OF THE INVENTION

In one aspect, the invention specifies a piezoelectric component having high reliability.

A piezoelectric multilayer component as an intermediate product is specified, which comprises a stack of piezoelectric layers arranged one above another. The stack comprises an active region having electrode layers arranged between the piezoelectric layers and at least one inactive region. The active region in the end product of the piezoelectric multilayer component is provided for the purpose of deforming when a voltage is applied to the electrode layers. The inactive region comprises at least one sacrificial layer. The sacrificial layer comprises an electrically insulating material and a metal. The metal is diffusible at least partly from the sacrificial layer into the piezoelectric layers of the inactive region by means of heating the multilayer component.

In particular, the end product of the piezoelectric component can be embodied as a piezo-actuator of multilayer design. The active region of the component comprises electrode layers arranged between the piezoelectric layers. When a voltage is applied to the electrode layers, a deformation of the piezoelectric material in the active regions occurs. If the component is a piezo-actuator, then this deformation can also be designated as a piezoelectric stroke.

The deformation of the inactive region is smaller than the deformation of the active region when a voltage is applied to the electrode layers of the active region. Preferably, the inactive region has no deformation as a response of the piezoelectric material arranged in the inactive region to an applied voltage. In particular, the inactive region preferably comprises no electrode layers. The inactive region can be provided for the electrical insulation of the active region, for example from a housing in which the component is incorporated. For example, the inactive region can be utilized as an end portion of the component for clamping the component.

The piezoelectric layers of the component, in particular of the intermediate product, can be produced from so-called green sheets, which comprise a ceramic powder beside further constituents such as sintering auxiliaries, for instance. The electrode layers of the active region can be applied to the green sheets, for example in a screen printing method. The green sheets are subsequently stacked, such that an intermediate product of the component arises, and jointly sintered, with the result that a monolithic basic body arises as end product from the intermediate product of the component.

During the heating of the intermediate product, in particular during the sintering process, metal diffuses from the electrode layers of the active region into the piezoelectric layers of the active region. In case that the inactive region comprises no electrode layers, no diffusion of metal into the piezoelectric layers takes place in the inactive region. This leads to different metal concentrations in the piezoelectric layers of active region and inactive region. In particular, the metal that has diffused from the electrode layers into the piezoelectric layers of the active region accelerates the sintering shrinkage in the active region, especially at high sintering temperatures. This results in different sintering shrinkage properties and, consequently, in different sintering shrinkage temperatures of the active region and of the inactive region and, as a consequence thereof, in the formation of mechanical stresses particularly at the boundary between the active region and the inactive region. The mechanical stresses that occur can lead to the formation of cracks at the boundary between the active region and the inactive region during the heating of the intermediate product or during the operation of the end product. The cracks can result in the failure of the piezoelectric actuator. The reduction of the occurrence of cracks can thus make a crucial contribution to an increase of the reliability and the lifetime of the actuator.

In the case of the intermediate product described here, the inactive region comprises at least one sacrificial layer containing metal. During the heating of the intermediate product, in particular during the sintering process, the metal diffuses from the sacrificial layer of the inactive region into the piezoelectric layers of the inactive region. As a result, the sintering shrinkage in the inactive region is approximated to the sintering shrinkage in the active region. The sacrificial layer preferably comprises a quantity of metal such that, after the sintering of the intermediate product, the piezoelectric layers in the active region and in the inactive region have the same concentration of metal. Furthermore, the quantity of insulating material contained in the sacrificial layer is preferably chosen such that in the end product the insulating effect of the inactive region is ensured despite the metal contained in the sacrificial layer.

The piezoelectric component described consequently has the advantage that, as a result of the metal contained in the sacrificial layer, preferably identical metal concentrations are brought about in the piezoelectric layers in the active region and in the inactive region and, as a result, an adaptation of the sintering shrinkage properties of active and inactive regions of the stack can be achieved. The formation of cracks, particularly at the boundary between active and inactive regions, for example during the heating of the component or else during the operation of the end product, can thus be avoided or at least reduced.

The sacrificial layer may comprise an organic binder beside the metal and the electrically insulating material, which binder preferably volatilizes prior to the actual sintering of the intermediate product by means of a suitable thermal treatment.

Furthermore, a piezoelectric multilayer component as an end product is specified, which comprises a stack of piezoelectric layers arranged one above another. The stack comprises an active region having electrode layers arranged between the piezoelectric layers and at least one inactive region. The active region is provided for the purpose of deforming when a voltage is applied to the electrode layers. The piezoelectric layers of the active region and of the inactive region preferably comprise metal in substantially the same concentration.

In this case, “substantially the same concentration” is taken to mean a concentration of metal in the piezoelectric layers of the active and inactive regions which is chosen such that the differences in the sintering shrinkage of active and inactive regions are small enough that no formation of cracks occurs during the sintering process. In this case, the piezoelectric layers of the active region and of the inactive region may comprise the same metal. As an alternative thereto, the metal in the piezoelectric layers of the active region may be different than the metal in the piezoelectric layers of the inactive region.

The piezoelectric layers of the active region and of the inactive region preferably have the same chemical composition, in particular the same metal concentration. The piezoelectric layers of the active region and of the inactive region preferably comprise the same metal. Preferably, the piezoelectric layers of the active region and of the inactive region comprise the metal contained in the electrode layers of the active region, for example copper. As a result, an adaptation of the sintering shrinkage properties of the active region and of the inactive region can be achieved.

The quantity of metal contained in the inactive region is advantageously chosen such that the inactive region, despite the metal contained in the piezoelectric layers of the inactive region, has an electrically insulating effect with respect to the active region and with respect to external electrodes fitted to the actuator.

In one advantageous embodiment of the intermediate product, the number of sacrificial layers in the inactive region and the quantity of metal in the respective sacrificial layer are chosen in such a way that, after the heating of the multilayer component, the piezoelectric layers assigned to the inactive region have the same concentration of metal as the piezoelectric layers assigned to the active region. Furthermore, the number of sacrificial layers in the inactive region and the quantity of metal in the respective sacrificial layer are chosen in such a way that the insulating properties of the inactive region, in particular the insulating effect of the inactive region with respect to the external electrodes fitted to the actuator, are still ensured.

The quantity of metal contained in the sacrificial layer is chosen in a manner dependent on how much metal the piezoelectric layers of the inactive region can take up during the heating of the intermediate product. This is dependent, inter alia, on the thickness of the piezoelectric layers of the inactive region. Preferably, the sacrificial layer comprises at least just as much metal as can diffuse into the piezoelectric layers of the inactive region during heating.

In one embodiment of the intermediate product, the sacrificial layer has a weight ratio between metal and insulating material which is in a range of between 1:5 and 1:50.

In one embodiment of the intermediate product, the piezoelectric layers comprise a piezoceramic material.

For example, the piezoelectric layers comprise a lead zirconate titanate (PZT) ceramic. In particular, the piezoelectric layers of the active region and of the inactive region may comprise the same piezoceramic material.

In one embodiment of the intermediate product, the sacrificial layer comprises as insulating material the same piezoelectric material as the piezoelectric layers.

As a result, the diffusion behavior of the metal in the inactive region and in the active region can be adapted particularly well to one another. Preferably, after the heating of the component, the sacrificial layers have the same composition as the piezoelectric layers of the inactive region and are no longer discernable as separate layers.

The sacrificial layer comprises at least an amount of metal such that a saturation of the piezoelectric layers with metal may be achieved as a result of the diffusion of the metal from the sacrificial layer into the piezoelectric layers of the inactive region. Preferably, during the sintering process, as much metal diffuses from the electrode layers of the active region into the piezoelectric layers of the active region and as much metal diffuses from the sacrificial layer into the piezoelectric layers of the inactive region that a saturation state of metal in the piezoelectric layers in the active region and in the inactive region is achieved. In case that the sacrificial layer comprises more metal than can be taken up by the piezoelectric layers of the inactive region during the sintering process, then the residual metal, for example in the form of small metal particles, remains in the sacrificial layer after the sintering process, with the result that the sacrificial layer can also be discernable in the end product.

One embodiment of the intermediate product provides for the sacrificial layer to comprise a ceramic powder having a particle size of greater than or equal to 0.2 μm and less than or equal to 1.5 μm.

One embodiment of the intermediate product provides for the sacrificial layer to comprise a metal powder having a particle size of greater than or equal to 0.01 μm and less than or equal to 3.0 μm.

For the particle size, in this case a median value d50 of the distribution of the particle sizes in the sacrificial layer is preferably specified. The particle size of the ceramic powder before the heating of the intermediate product may be greater than or equal to 0.2 μm and less than or equal to 1.5 82 m and is preferably greater than or equal to 0.4 μm and less than or equal to 1.5 μm. The particle size of the metal powder before the heating of the intermediate product may be greater than or equal to 0.01 μm and less than or equal to 3.0 μm and is preferably greater than or equal to 0.4 μm and less than or equal to 1.5 μm. Preferably, the metal powder has the same particle size as the metal of the electrode layers of the active region. Furthermore, the ceramic powder preferably has the same particle size as the piezoelectric material of the piezoelectric layers of the active region and of the inactive region. This is particularly expedient in order to bring about an identical diffusion behavior of the metal in the active region and in the inactive region and thus to achieve an adaptation of the sintering shrinkage of active region and inactive region during the heating of the component.

A further embodiment provides for the distance between two sacrificial layers in the inactive region to be 0.3 to 3.0 times the magnitude of the distance between two adjacent electrode layers in the active region.

The distance between two sacrificial layers in the inactive region is preferably of exactly the same magnitude as the distance between two adjacent electrode layers in the active region. By adapting the distance between two sacrificial layers to the distance between two electrode layers, an identical concentration distribution of the metal in the piezoelectric layers of the active and inactive regions can preferably be achieved. In this case, the piezoelectric layers in the transition region between piezoelectric layer and sacrificial layer in the inactive region of the stack and also in the transition region between piezoelectric layer and electrode layer in the active region of the stack may have a higher metal concentration than in a region of the piezoelectric layer that is further away from the transition region.

A further embodiment of the intermediate product provides for the sacrificial layer to have a structuring in a plane perpendicular to the stacking direction.

In this case, the sacrificial layer can have an interrupted structure, respectively cover only a part of a piezoelectric layer of the inactive region. The sacrificial layer may be embodied, for example, as an arrangement of islands applied on a piezoelectric layer in the inactive region. The sacrificial layer can have cutouts, for example, in particular in such a way that as a net structure it covers only a part of the piezoelectric layer of the inactive region.

As a result of the structuring of the sacrificial layer, the quantity of metal diffusing into the piezoelectric layers of the inactive region during the sintering process can additionally be controlled.

One embodiment of the intermediate product provides for the geometrical application pattern of the sacrificial layer to correspond to the geometrical application pattern of the electrode layers in the active region.

As a result of identical application patterns of sacrificial layer and electrode layer, the diffusion behavior of the metal from the sacrificial layer may be matched particularly well to the diffusion behavior of the metal from the electrode layers and, consequently, the difference in sintering shrinkage in the active region and in the inactive region may be further minimized.

Alongside the piezoelectric multilayer component as an intermediate product and also as an end product, a method for producing a piezoelectric multilayer component as an intermediate product is specified.

In this case, a method for producing the above-described intermediate product for a piezoelectric multilayer component is specified, which comprises the following steps:

A first step involves determining a quantity of metal and in particular the weight of the metal for the sacrificial layer. In this case, the quantity of metal is provided for at least partial diffusion into the piezoelectric layers assigned to the inactive region. A further step involves determining a maximum weight for the sacrificial layer. A next step involves determining the quantity of the insulating material, and in particular the weight of the insulating material, for the sacrificial layer from the difference between the maximum weight of the sacrificial layer and the weight of the quantity of metal determined for the sacrificial layer. A further step involves forming the sacrificial layer from the predetermined quantity of metal and of insulating material in those piezoelectric layers which are assigned to the inactive region. A last step involves forming the stack of the component, said stack comprising at least one piezoelectric layer formed according to the previous steps for the inactive region and piezoelectric layers arranged one above another and electrode layers arranged therebetween for the active region.

The quantity of insulating material present in the sacrificial layer is preferably determined such that the insulating effect of the inactive region, despite the metal contained in the sacrificial layer, is still ensured.

The quantity of metal in the sacrificial layer is preferably at least of a magnitude such that, during the sintering process, the amount of metal that may diffuse from the sacrificial layer into the piezoelectric material of the inactive region is just as much as the amount of metal that diffuses from the electrode layers into the piezoelectric material in the active region. An adaptation of the sintering shrinkage properties of active and inactive regions can thus be achieved. The quantity of metal in the sacrificial layer is dependent on the chemical composition of the piezoelectric material in the inactive region. In addition, the quantity of the metal is dependent on the type of the metal. From this and from the volume of the inactive region it is possible to determine the metal weight per sacrificial layer.

The maximum weight of the sacrificial layer is dependent on the weight of the metal. The layer thickness of the sacrificial layer, and thus the maximum weight of the sacrificial layer, is additionally dependent on the method, for example a screen printing method, by which the sacrificial layer is applied to the piezoelectric layer of the inactive region.

One configuration of the method provides for heating, in particular sintering, the intermediate product in order to obtain the end product for the piezoelectric multilayer component.

The piezoelectric multilayer component produced as an intermediate product is sintered, wherein the metal at least partly diffuses from the sacrificial layer into the piezoelectric layers of the inactive region and the metal diffuses from the electrode layers into the piezoelectric layers of the active region. The piezoelectric layers of the end product produced by sintering, in particular of the active and inactive regions of the end product, preferably have substantially the same metal concentrations and accordingly identical sintering shrinkage properties.

### BRIEF DESCRIPTION OF THE DRAWINGS

Piezoelectric components are described by way of example below in order to elucidate the embodiments described here in conjunction with FIGS. 1 to 3.

FIG. 1 shows a schematic illustration of an end product of a piezoelectric actuator;

FIG. 2 shows a schematic illustration of a partial region of an intermediate product of a piezoelectric actuator in accordance with one embodiment; and

FIGS. 3A to 3F show various embodiments of a sacrificial layer.

In the exemplary embodiments and figures, identical or identically acting component parts may in each case be provided with the same reference signs. The elements illustrated and their size relationships among one another should not be regarded as true to scale, in principle; rather, individual elements, such as, for example, layers, structural parts, components and regions, may be illustrated with exaggerated thickness or size dimensions in order to enable better illustration or in order to afford a better understanding.

### DETAILED DESCRIPTION OF ILLUSTRATIVE EMBODIMENTS

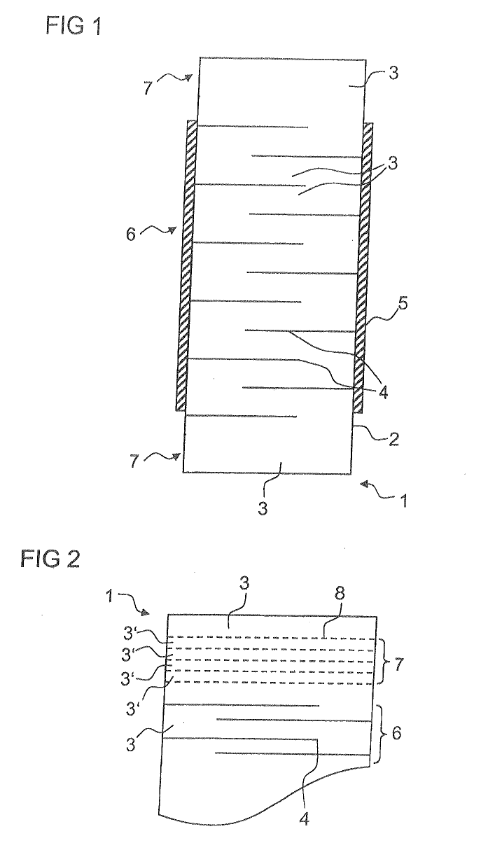

FIG. 1 shows an end product of a multilayer piezoelectric actuator 1 comprising a stack 2 composed of a plurality of piezoelectric layers 3 arranged one above another.

Along the stacking direction, the stack 2 is subdivided into one active region 6 and two inactive regions 7. The inactive regions 7 adjoin the active region 6 in the stacking direction and form the end portions of the stack 2. The active region 6 of the stack 2 comprises electrode layers 4 arranged between the piezoelectric layers 3. In order to be able to make contact with the electrode layers 4 in the active region 6 in a simple manner, the actuator 1 is embodied such that only electrode layers 4 respectively assigned to the same electrical polarity extend as far as an edge region of the actuator 1. The electrode layers 4 assigned to the other electrical polarity at this location do not extend right to the edge of the actuator 1. Accordingly, the electrode layers 4 are respectively embodied in the form of intermeshed combs. Via contact areas in the form of metallizations 5 at the outer side of the stack 2, an electrical voltage can be applied to the electrode layers 4. When a voltage is applied to the electrode layers 4, a deformation of the piezoelectric material in the active region 6 occurs.

The inactive regions 7 comprise no electrode layers 4. When a voltage is applied to the metallizations 5, no electric field is generated in the inactive regions 7. In particular, no deformation of the piezoelectric material in the inactive regions 7 occurs when a voltage is applied to the metallizations 5. Consequently, the inactive regions 7 do not contribute to the stroke of the piezoelectric actuator 1. The inactive regions 7 serve for electrically insulating the active region 6. The inactive regions 7 can, for example, also be used for clamping the actuator 1.

For example, thin films composed of a piezoceramic material, for example lead zirconate titanate (PZT), are used for the production of the piezoelectric layers 3 of the actuator 1. From one film it is possible to form one ply of a piezoelectric layer 3 (see plies 3′ in the piezoelectric layers 3 of the intermediate product in FIG. 2). A piezoelectric layer 3 may comprise a plurality of plies 3′ of a piezoelectric material (see FIG. 2). In the end product of the actuator 1, in particular after the sintering of the intermediate product, as evident from FIG. 1, the plies 3′ may possibly no longer be distinguished from one another.

The same piezoelectric material is used in the entire actuator 1. The piezoelectric material can additionally be provided with dopants. By way of example, the piezoelectric material can be doped with neodymium or with a mixture of zinc and niobium. In order to form the electrode layers 4 of the active region 6, a metal paste, for example a copper paste, a silver paste or a silver-palladium paste, can be applied to the films in a screen printing method. Films composed of the same piezoelectric material as in the active region 6 are used for the inactive regions 7. However, the films for the inactive regions 7 do not comprise a printing of the metal paste for producing electrode layers 4. All of the films are stacked, pressed and jointly sintered at temperatures of between 900° C. and 1200° C., with the result that a monolithic basic body arises as an end product.

FIG. 2 shows a schematic illustration of a partial region of an intermediate product of a piezoelectric actuator 1 in accordance with one embodiment. In particular, FIG. 2 shows an inactive region 7 and also a part of the active region 6 of a multilayer piezoelectric actuator 1, said active region adjoining the inactive region 7. All features of the actuator 1 mentioned in the description of FIG. 1 also apply to the end product according to the invention, which can be formed from the intermediate product described below, with the exception of the fact that the end product comprises metal in the piezoelectric layers 3 of the inactive region 7, and, in particular, the metal concentration in the piezoelectric layers 3 of the active region 6 and of the inactive region 7 is identical. This is explained in detail below.

In the exemplary embodiment illustrated here, the inactive region 7 comprises a piezoelectric layer 3. The piezoelectric layer 3 of the inactive region 7 comprises, as already described in connection with FIG. 1, a multiplicity of plies 3′ of the piezoelectric material, for example PZT.

The active region 6 consists of a plurality of piezoelectric layers 3, which likewise comprise a multiplicity of plies 3′ of the piezoelectric material (not explicitly illustrated). The inactive region 7 comprises the same piezoelectric material as the active region 6. Electrode layers 4 contact-connected to different polarities respectively are introduced between the individual piezoelectric layers 3 of the active region 6.

The layer thickness of the piezoelectric layer 3 in the inactive region 7 is greater, preferably at least ten times greater, than the layer thickness of a piezoelectric layer 3 in the active region 6. The greater the thickness of the piezoelectric layer 3 in the inactive region 7, the better the electrical insulation of the active region 6 by the inactive region 7 of the actuator 1. Alternatively, however, the layer thickness of a piezoelectric layer 3 assigned to the inactive region 7 may also be less than the layer thicknesses of the piezoelectric layers 3 in the active region 6, particularly if the inactive region 7 comprises a plurality of piezoelectric layers 3.

In order to adapt the sintering shrinkage in the active region 6 and in the inactive region 7 and thereby to avoid the formation of cracks at the boundary between active region 6 and inactive regions 7, in particular during the sintering process, sacrificial layers 8 (indicated by dashed lines for illustration purposes) are introduced into the piezoelectric layer 3 of the inactive region 7, and in particular onto the plies 3′ of the piezoelectric material in the inactive region 7.

The sacrificial layer 8 comprises an organic binder and a mixture composed of a metal powder and an electrically insulating material, a ceramic powder in this exemplary embodiment. In this case, the ceramic powder of the sacrificial layer 8 has the same chemical composition as the piezoelectric material of the piezoelectric layers 3 in the active region 6 and in the inactive regions 7, for example PZT. The metal powder comprises the same metal as the electrode layers 4 in the active region of the actuator 1. By way of example, the metal powder comprises copper. As an alternative thereto, in case that a silver paste or a silver-palladium paste is used for the electrode layers 4 of the active region 6, the metal powder of the sacrificial layer 8 comprises silver. The metal powder comprises no palladium, for example, since palladium has only a low diffusibility during the heating of the actuator 1.

The metal present in the sacrificial layer 8 is provided for diffusing into the piezoelectric layer 3, in particular into plies 3′ of the piezoelectric layer 3 which adjoin the sacrificial layer 8, of the inactive region 7 during the sintering process. This brings about the same metal concentration in the piezoelectric layers 3 in the active region and in the inactive region 7 during the sintering process. An adaptation of the sintering shrinkage properties of the active region 6 and of the inactive region 7 is achieved as a result. The formation of cracks during the sintering process is thus avoided or at least reduced, as described in detail later.

The ceramic powder in the sacrificial layer 8 preferably has a particle size of greater than or equal to 0.4 μm and less than or equal to 1.5 μm. The metal powder preferably has a particle size of greater than or equal to 0.4 μm and less than or equal to 1.5 μm. The metal powder can have, in particular, a smaller particles size than the ceramic powder, which brings about better diffusion of the metal particles into the piezoelectric layer 3 of the inactive region 7.

Preferably, the metal powder has the same particle size as the metal of the electrode layers 4.

As illustrated in FIG. 2, a sacrificial layer 8 can be applied to each ply 3′ of the piezoelectric material in the inactive region 7. Alternatively, a sacrificial layer 8 can be applied only to selected plies 3′ of the piezoelectric material in the inactive region 7, for example to every second ply 3′. As evident from FIG. 2, the distance between two plies 3′ of the piezoelectric material in the inactive region 7, said plies being provided with the sacrificial layer 8, is of approximately the same magnitude as the distance between two adjacent electrode layers 4 in the active region 6.

During the sintering process, at least a part of the metal diffuses from the sacrificial layer 8 into the plies 3′—adjoining the sacrificial layer 8—of the piezoelectric layer 3 in the inactive region 7. After the sintering process, the piezoelectric material in the active region 6 and the piezoelectric material in the inactive regions 7 consequently have the same chemical composition and, in particular, the same quantity of metal.

The end product of the actuator 1 produced by means of the sintering may, as already mentioned above, look like the end product described in connection with FIG. 1, apart from the fact that the metal concentration in the piezoelectric layers 3 in the active region 6 and inactive region 7 is identical in the case of the end product described here.

Since the metal present in the sacrificial layer 8 diffuses into the piezoelectric layer 3 of the inactive region 7 approximately completely, in particular until the saturation state is attained, during sintering and the sacrificial layer 8 additionally contains the same ceramic material as the piezoelectric layers 3 of the active region 6 and of the inactive region 7, after the sintering process the sacrificial layer 8 can no longer or only hardly be distinguished from the piezoelectric material of the piezoelectric layers 3 of the active and inactive regions 6, 7. In other words, after the sintering process there is preferably no difference between the piezoelectric material in the active region 6 and in the inactive region 7.

If the sacrificial layers 8 contain more metal than can be taken up by the piezoelectric layer 3 of the inactive region 7 during the sintering process, and in particular until the saturation state is attained, then the residual metal, for example in the form of small metal particles, may remain in the sacrificial layers 8 after the sintering process. In this case, sacrificial layers 8 in the inactive region 7 are discernable also in the end product of the actuator 1, that is to say after the sintering of the intermediate product.

Even in case that parts of the metal remain in the sacrificial layers 8, no electrical connection of the metal in the sacrificial layer 8 to the metallizations 5—illustrated in FIG. 1—at the outer side of the stack 2 is present in the end product. In particular, no electrode layers of the inactive region 7 that are connected to the metallizations 5 arise from the sacrificial layers 8.

The sacrificial layer 8, like the electrode layers 4 in the active region 6, may be introduced onto the plies 3′ of the piezoelectric material of the inactive region in a screen printing method. In this case, the sacrificial layer 8 may have a structuring in a plane perpendicular to the stacking direction. In particular, by applying the sacrificial layer 8 only to local regions of a ply 3′ of the piezoelectric material in the inactive region 7 and through a suitable choice of the form and size of that area of the ply 3′ which is printed with the sacrificial layer 8, it is possible additionally to control the quantity of metal which diffuses into the piezoelectric layer 3 of the inactive region 7 during the sintering process.

As a result of identical application patterns of sacrificial layer 8 and electrode layer 4, the diffusion behavior of the metal from the sacrificial layer 8 can be matched further to the diffusion behavior of the metal from the electrode layers 4 and the difference in sintering shrinkage can thus be minimized further. In particular, thereby an identical metal concentration of the piezoelectric layer 3 of the inactive region 7 and of the piezoelectric layers 3 of the active region 6 after the sintering process may be achieved.

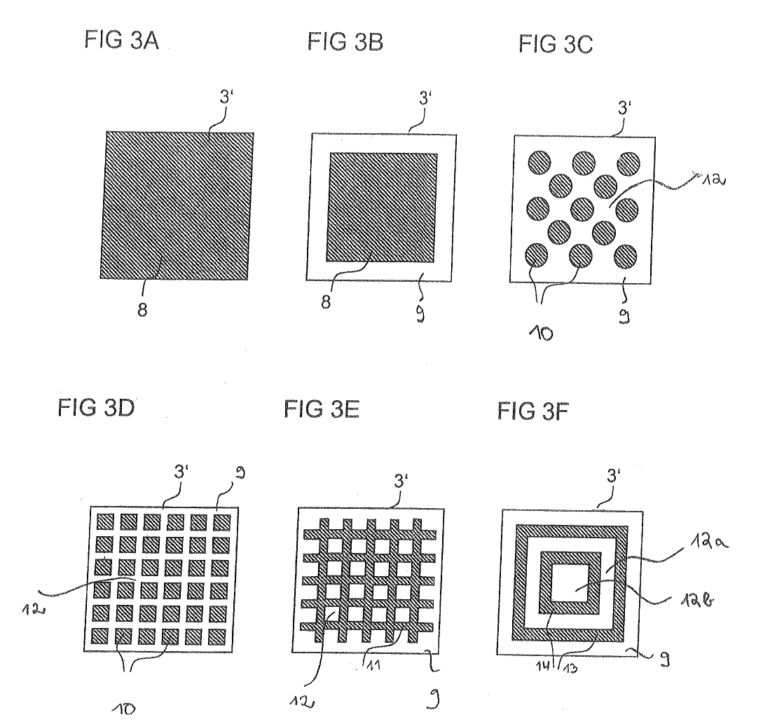

FIGS. 3A to 3F show various embodiments of a sacrificial layer 8.

In particular, FIG. 3A shows the plan view of a sacrificial layer 8 which covers the entire top side of a ply 3′ of the piezoelectric material in the inactive region 7.

As an alternative thereto, the sacrificial layer 8, as already mentioned, can be applied to the ply 3′ analogously to the application pattern of an electrode layer 4 in the active region 6 of the stack 2. In this case, the sacrificial layer 8 would, for example, be applied to the complete top side of the ply 3′ apart from a cutout at an edge of the ply 3′ (not explicitly illustrated).

FIG. 3B shows the plan view of a sacrificial layer 8 which covers the entire top side of a ply 3′ of the piezoelectric material in the inactive region 7 apart from a cutout 9 extending circumferentially at the edge of the ply 3′. As a result of the cutout 9, it is possible to reduce the diffusion of metal from the sacrificial layer 8 into the edge region of the ply 3′ of the piezoelectric material in the inactive region 7. As a result, it is possible to increase the insulating effect of the inactive region 7 in comparison with the embodiment of the sacrificial layer 8 as illustrated in FIG. 3A. In particular, the cutout 9 is particularly advantageous in order still to ensure the electrically insulating effect of the inactive region 7 with respect to the metallizations 5 fitted to the actuator 1 (see FIG. 1).

FIG. 3C shows the plan view of a structured sacrificial layer 8. In this case, the material of the sacrificial layer 8 is applied in the form of individual islands 10 to the top side of the ply 3′. Cutouts 12 can be discerned between the islands 10, such that the sacrificial layer 8 covers only part of the top side of the ply 3′. By varying the size of the cutouts 12, it is possible to further control the quantity of the metal which diffuses from the sacrificial layer 8 into the piezoelectric layers 3 of the inactive region 7.

The islands 10 are, for example, circular and arranged at regular distances with respect to one another. A circumferentially extending cutout 9 can be discerned at the edge of the ply 3′. As already mentioned, the electrically insulating effect of the inactive region 7 with respect to the metallizations 5 is ensured by the cutout 9.

FIG. 3D shows an embodiment of the sacrificial layer 8 in which the islands 10 are square.

FIG. 3E shows a sacrificial layer 8 which is applied as a type of net structure 11 on a ply 3′ of the piezoelectric material in the inactive region 7. Consequently, the sacrificial layer 8 is applied to the ply 3′ in a continuous structure enclosing square cutouts 12. A circumferentially extending cutout 9 can once against be discerned at the edge of the ply 3′.

FIG. 3F shows a sacrificial layer 8 which is applied as an arrangement of concentric, frame-shaped regions 13, 14 on a ply 3′. In this case, the regions 13, 14 can have circular or square contours. They can be understood as ring-shaped islands having a common center. In particular, the frame-shaped region 14 of the sacrificial layer 8 is arranged concentrically within the frame-shaped region 13. A cutout 12a can be discerned between the frame-shaped regions 13, 14. Furthermore, a cutout 12b of the sacrificial layer 8 is situated within the frame-shaped region 14, in particular in the center of the ply 3′. A circumferentially extending cutout 9 is provided at the edge of the ply 3′. By varying the number and form of the frame-shaped regions and the size of the cutouts 9, 12, it is possible to control the quantity of the metal which diffuses into the piezoelectric layers 3 of the inactive region 7 and thus adapt it to the quantity of the metal which diffuses from the electrode layers 4 of the active region 6.

1. A piezoelectric multilayer component comprising a stack of piezoelectric layers arranged one above another, wherein the stack comprises an active region having electrode layers arranged between the piezoelectric layers and at least one inactive region, wherein the active region in the end product of the piezoelectric multilayer component is provided for the purpose of deforming when a voltage is applied to the electrode layers, wherein the inactive region comprises at least one sacrificial layer comprising an electrically insulating material and a metal, wherein the metal is diffusible at least partly from the sacrificial layer into the piezoelectric layers of the inactive region by means of heating the multilayer component.

2. The piezoelectric multilayer component according to claim 1, wherein the number of sacrificial layers in the inactive region and the quantity of metal in the respective sacrificial layer are chosen in such a way that, after the heating of the multilayer component, the piezoelectric layers assigned to the inactive region have substantially the same concentration of metal as the piezoelectric layers assigned to the active region.

3. The piezoelectric multilayer component according to claim 1, wherein the sacrificial layer has a weight ratio between metal and insulating material which is in a range of between 1:5 and 1:50.

4. The piezoelectric multilayer component according to claim 1, wherein the piezoelectric layers comprise a piezoceramic material.

5. The piezoelectric multilayer component according to claim 1, wherein the sacrificial layer comprises as insulating material the same piezoelectric material as the piezoelectric layers.

6. The piezoelectric multilayer component according to claim 1, wherein the sacrificial layer comprises the same metal as the electrode layers.

7. The piezoelectric multilayer component according to claim 5, wherein the sacrificial layer comprises a ceramic powder having a particle size of greater than or equal to 0.2 μm and less than or equal to 1.5 μm.

8. The piezoelectric multilayer component according to claim 1, wherein the sacrificial layer comprises a metal powder having a particle size of greater than or equal to 0.01 μm and less than or equal to 3.0 μm.

9. The piezoelectric multilayer component according to claim 1, wherein a distance between two sacrificial layers in the inactive region is 0.3 to 3.0 times a magnitude of the distance between two adjacent electrode layers in the active region.

10. The piezoelectric multilayer component according to claim 1, wherein the sacrificial layer has a structuring in a plane perpendicular to the stacking direction.

11. The piezoelectric multilayer component according to claim 1, wherein a geometrical application pattern of the sacrificial layer corresponds to the a geometrical application pattern of the electrode layers in the active region.

12. A piezoelectric multilayer component, comprising a stack of piezoelectric layers arranged one above another, wherein the stack comprises an active region having electrode layers arranged between the piezoelectric layers and at least one inactive region, wherein the active region is provided for the purpose of deforming when a voltage is applied to the electrode layers, wherein the piezoelectric layers of the active region and of the inactive region comprise a metal in substantially the same concentration.

13. A piezoelectric multilayer component as an end product which is formed from an intermediate product according to claim 1, by sintering the intermediate product.

14. The method of claim 16, wherein forming the intermediate product comprises:
A) determining a quantity of metal for the sacrificial layer which is provided for at least partial diffusion into the piezoelectric layers assigned to be inactive regions,
B) determining a maximum weight for the sacrificial layer,
C) determining the quantity of the insulating material for the sacrificial layer from the difference between the maximum weight of the sacrificial layer and the weight of the quantity of metal determined for the sacrificial layer,
D) forming the sacrificial layer from the predetermined quantity of metal and of insulating material in those piezoelectric layers which are assigned to the inactive region,
E) forming the stack comprising at least one piezoelectric layer formed according to steps A) to D) for the inactive region and piezoelectric layers arranged one above another and electrode layers arranged therebetween for the active region.

15. The method according to claim 14, comprising sintering the intermediate product in order to obtain the end product for the piezoelectric multilayer component.

16. A method of forming a piezoelectric multilayer component, the method comprising forming an intermediate product comprising a stack of piezoelectric layers arranged one above another, wherein the stack comprises an active region having electrode layers arranged between the piezoelectric layers and at least one inactive region, wherein the active region in the end product of the piezoelectric multilayer component is provided for the purpose of deforming when a voltage is applied to the electrode layers, wherein the inactive region comprises at least one sacrificial layer comprising an electrically insulating material and a metal, wherein the metal is diffusible at least partly from the sacrificial layer into the piezoelectric layers of the inactive region by means of heating the multilayer component.
